(19) United States
(12) Patent Application Publication
(10) Pub. No.: US 2025/0192128 A1
(43) Pub. Date: Jun. 12, 2025

(54) Artificial Intelligence Engine and Memory Interoperation

(71) Applicant: Google LLC, Mountain View, CA (US)

(72) Inventors: Hongil Yoon, San Jose, CA (US); Li-Sheng Weng, San Diego, CA (US); Chin Kwan Kim, San Diego, CA (US)

(73) Assignee: Google LLC, Mountain View, CA (US)

(21) Appl. No.: 18/968,482

(22) Filed: Dec. 4, 2024

Related U.S. Application Data
(60) Provisional application No. 63/609,253, filed on Dec. 12, 2023.

(51) Int. Cl. H01L 25/18; H05K 1/18; H10B 80/00

(52) U.S. Cl. CPC H01L 25/18; H05K 1/18; H10B 80/00; H05K 2201/10159

(57) ABSTRACT

Artificial intelligence (AI) functionality is becoming pervasive in electronic devices, including mobile ones in which interior volume and printed circuit board (PCB) area are constrained. AI processing also taxes computing hardware differently. Some tasks are relatively compute-bound, and some tasks are relatively memory-bound. Balancing these competing factors is challenging. In example implementations, AI engines are disposed in various locations to facilitate compute-bound and memory-bound AI tasks while efficiently utilizing area of a PCB. For example, a first package assembly can include nonvolatile memory and DRAM with processor-in-memory realized as at least one AI processing unit for memory-bound tasks. The first package assembly can also include an AI engine with greater processing capabilities for compute-bound tasks. Further, a second package assembly, which is coupled to the first package assembly, can include an SoC with a still more-capable AI engine. This enables AI tasks to be assigned to an appropriate AI engine.

### CROSS-REFERENCE TO RELATED APPLICATION(S)

This application claims the benefit of U.S. Provisional Patent Application No. 63/609,253 that was filed on 12 Dec. 2023, the disclosure of which is incorporated by reference herein in its entirety.

### BACKGROUND

Computing and other electronic devices play integral roles in manufacturing, communication, transportation, healthcare, commerce, social interaction, entertainment, and other services. For example, electronic devices power the server farms that provide cloud-based, distributed computing functionality for commerce, communication, and some artificial intelligence (AI) services. Electronic devices are also embedded in many different types of modern equipment, from medical devices to appliances and from vehicles to industrial tools. Personal electronic devices enable portable video viewing and convenient access to smart digital assistants. Additionally, one versatile electronic device—the smartphone—has practically become a necessity to have within arm's reach.

To provide diverse functionalities for these various services and purposes, electronic devices typically include multiple components, such as one or more integrated circuits that may be packaged for use in an electronic device. Accordingly, computer engineers, electrical engineers, and other designers of electronic devices endeavor to improve the operation or architecture of the various components of an electronic device to facilitate their use in providing services.

### SUMMARY

This document describes hardware and techniques for integrated circuit (IC) packages that can facilitate artificial intelligence (AI) operations. In some AI use cases, AI functionality is memory bound—meaning that AI functionality is more limited by memory capabilities than processor performance. In other AI use cases, AI functionality is compute bound—meaning that AI functionality is more limited by processor performance than memory capabilities. Generally, AI functionality can be provided in multiple environments, including in cloud environments like server farms and in consumer devices like laptops and smartphones. In space-constrained devices, like many mobile devices, providing AI functionality that can accommodate multiple types of AI use cases is challenging. Certain described implementations provide computing architectures that combine memory and one or more AI engines to facilitate multiple types of AI functionality.

In example implementations, an apparatus includes a package assembly that includes a first IC, a second IC, and a third IC. The first IC includes nonvolatile memory. The second IC includes dynamic random-access memory (DRAM) that is realized processor-in-memory (PIM). Here, the PIM includes an artificial intelligence (AI) engine. The third IC also includes an AI engine. The package assembly is manufactured with multiple pins that are coupled to the first IC, the second IC, and the third IC. The multiple pins are exposed to an exterior of the package assembly to provide electrical communication to the first, second, and third ICs. In some cases, the first IC, the second IC, and the third IC are combined into the same package (e.g., a single package) in the package assembly.

In example aspects, an AI engine of a PIM is relatively “closer” to a memory array, which can increase memory bandwidth, (e.g., as part of the second IC) as compared to an AI engine that is part of a different IC (e.g., the third IC). Accordingly, the PIM AI engine of the second IC may be assigned relatively memory-bound AI tasks. In further example aspects, the AI engine of the third IC may be more complex or more capable than any single instance of an AI engine that is part of the PIM of the second IC. Accordingly, the “separate” AI engine of the third IC may be assigned relatively compute-bound AI tasks.

In other example implementations, an apparatus may include a second package assembly. The second package assembly may include, for instance, a system-on-chip (SoC) that has another AI engine. The second package assembly may also include a memory IC. In example aspects, the apparatus includes a printed circuit board (PCB) on which is mounted the “first” package assembly with a PIM AI engine and the second package assembly with an SoC. The two assemblies can be coupled together via an interconnect that is disposed on or is part of the PCB. In other example aspects, the second package assembly may be realized with a package-on-package (POP) structure, such as with the SoC as a “base” package and the memory IC as an “upper” package.

In still other example implementations, an apparatus includes a package assembly. The package assembly includes a first integrated circuit (IC) including nonvolatile memory. The package assembly also includes a second IC including dynamic random-access memory (DRAM) that includes processor-in-memory (PIM), with the PIM having an artificial intelligence (AI) engine. The package assembly additionally includes a third IC including an AI engine. The package assembly further includes multiple pins coupled to the first IC, the second IC, and the third IC. The multiple pins are exposed to an exterior of the package assembly.

In still other example implementations, an apparatus includes a package assembly. The package assembly includes a first integrated circuit (IC) including nonvolatile memory. The package assembly also includes a second IC including dynamic random-access memory (DRAM) that includes processor-in-memory (PIM) circuitry, with the PIM circuitry having an artificial intelligence (AI) engine. The package assembly further includes multiple pins coupled to the first IC and the second IC, with the multiple pins exposed to an exterior of the package assembly.

In still other example implementations, a method includes providing a first integrated circuit (IC) including nonvolatile memory. The method also includes providing a second IC including dynamic random-access memory (DRAM) that includes processor-in-memory (PIM), with the PIM comprising an artificial intelligence (AI) engine. The method additionally includes providing a third IC including an AI engine. The method further includes encasing the first IC, the second IC, and the third IC in a package.

Other example implementations are described herein or depicted in the accompanying drawings, which are hereby incorporated by reference into this description.

### BRIEF DESCRIPTION OF DRAWINGS

Apparatuses of and techniques for AI engine and memory interoperation are described with reference to the following drawings. The same numbers are used throughout the drawings to reference like features and components.

FIG. 1 illustrates an example apparatus with at least one printed circuit board (PCB) that can utilize AI engine and memory interoperation, with the PCB including first and second package assemblies.

FIG. 2 illustrates examples of first and second package assemblies, at least one of which may implement AI engine and memory interoperation.

FIG. 3 illustrates an example of a first package assembly that can include respective integrated circuits (ICs) for nonvolatile memory, dynamic random-access memory (DRAM) with processor-in-memory (PIM), and an AI engine.

FIGS. 3-1 to 3-4 illustrate examples of different interface and interconnection architectures for the first package assembly.

FIG. 4 illustrates another example of a first package assembly that can include respective ICs for nonvolatile memory and DRAM with PIM.

FIG. 5 illustrates an example of a second package assembly that can include respective ICs for a system-on-chip (SoC) and DRAM.

FIG. 6 is a flow diagram illustrating an example process for implementing AI engine and memory interoperation with respect to using a semiconductor package assembly.

FIG. 7 is a flow diagram illustrating an example process for implementing AI engine and memory interoperation with respect to manufacturing a semiconductor package assembly.

FIG. 8 illustrates various components of an example electronic device that can include hardware for AI engine and memory interoperation in accordance with one or more described aspects.

### DETAILED DESCRIPTION

### Overview

Electronic devices provide features and perform functions to make important contributions to modern society, such as those related to communication, safety, manufacturing, transportation, content creation, and information technology generally. These contributions can be enhanced by employing artificial intelligence (AI). For example, AI techniques, such as machine learning, are offering increasing benefits to users. These benefits include speech recognition, image recognition, photograph manipulation, and video enhancement. More recently, generative AI has evolved such that AI can produce textual documents, speech, music, images, video, and computing code, just to name a few examples. Much of generative AI is based on large-language models (LLMs), which make increasing demands on the memory capabilities of systems that are performing generative AI.

Generally, employing AI technologies involves the use of processors, memories, and the buses or other interconnects that link them together. Some types of AI tasks make greater demands on certain computing components than other types of AI tasks. For example, some AI functionalities are relatively more compute-bound while others are relatively more memory-bound. In other words, some functionalities are more limited by computing resources versus being more limited by memory resources. Some AI tasks, for instance, may involve a relatively smaller model size or working set size but relatively more computing resources to utilize the model. In contrast, other tasks may involve a relatively larger model size or working set size but relatively less computing horsepower to utilize the model.

Larger model and working set sizes (or, generally, “workloads”) usually result in higher memory demands. In some situations, increases to model or working set sizes can occur roughly in the following order of AI models from smaller workloads to larger workloads: real-time models, such as those for speech recognition; postshot and video models with larger resolutions, such as those for image enhancement; and larger speech models. The large language models (LLMs), on which many generative AI technologies are built, demand even more memory resources, including both memory storage and memory bandwidth resources. For instance, transferring models and working sets between memories and the logic that implements an AI engine can demand more bandwidth between the memory and the AI processing unit as the workloads increase in size. This demand for increased bandwidth can therefore impact an interconnect that couples the memory and AI unit together. Meeting the increased bandwidth may demand faster interconnects that are more complicated or larger, both of which can increase costs. Memory transfers also consume power, so the power consumption for AI tasks can increase as the data transfer amount or rate increases.

Thus, in addition to varying power demands, different AI technologies can place different demands on the processing, memory, and bandwidth resources of a computing device. Meeting these demands can be challenging, especially in a relatively resource-constrained apparatus, such as a mobile device. Accordingly, the AI performance that is provided by electronic devices, including mobile devices, can be improved by increasing or balancing the capabilities for processing compute-bound workloads and the capabilities for processing memory-bound workloads.

In one approach, an electronic device includes a system-on-chip (SoC) that is packaged with dynamic random-access memory (DRAM) (e.g., in a package-on-package (PoP) assembly). The SoC can include an AI engine. The electronic device also includes a separate package assembly with nonvolatile memory, such as flash memory. Although this approach places the DRAM nearer the AI engine as compared to if the DRAM were co-located with the flash memory, larger models and working sets may rely on the flash memory (e.g., that stores a large ML model). A less expensive approach can have one package that includes an SoC with an AI engine and another package that combines the DRAM with the flash memory. Although this latter approach can cost less than the POP assembly, the result is that the memory is located even farther from the AI engine of the SoC. The data communication between the AI processing unit of the SoC and the DRAM therefore creates a bottleneck for AI performance.

In another approach, processor-in-memory (PIM) can be used to move AI logic relatively closer to the AI model and working set that is stored in the memory. In such cases, a PIM logic unit can realize at least a portion of an AI engine. For instance, the PIM logic unit can be packaged with DRAM to reduce data movement between the DRAM and an SoC, which SOC may include a “main” AI engine. If a PIM logic unit is integrated with DRAM that is packaged with the SoC, however, the size of the resulting package can become so large as to be unwieldy or impractical for a printed circuit board (PCB), especially a PCB of a mobile device. If, on the other hand, a PIM logic unit is integrated with DRAM that is packaged with flash memory but separately from the SoC, then the data bottleneck between the DRAM and the “main” AI engine of the SoC can still produce unacceptable processing delays.

For yet another approach, this document describes implementations with two package assemblies. A first package assembly (or first package arrangement) includes multiple components: nonvolatile memory such as flash memory, DRAM, and an AI engine. In some cases, each of these three components is integrated in a respective integrated circuit (IC) of three ICs. The first package assembly may be realized with one package in which each of the ICs is encased in a same molding that includes multiple pins. Alternatively, the first package assembly may include multiple packages. Further, the DRAM may include at least one PIM logic unit that is configured as an AI engine. Any of these components may be realized with multiple ICs. For example, the first package assembly may include four DRAM IC chips.

A second package assembly (or second package arrangement) also includes multiple components: an SoC and DRAM. In some cases, each of these two components is integrated into a respective IC of two ICs. The second package assembly may be realized with two packages that are coupled together into a package-on-package (PoP) assembly. Further, the SoC may include an AI engine. The DRAM component, for instance, may also include multiple memory ICs in the first or second package assemblies, including multiple DRAM ICs within a single package or single package assembly.

In some aspects, the first package assembly may be deployed on a PCB or in an electronic device that does not include a second package assembly as described above. Further, in example aspects, a first package assembly can include nonvolatile memory and DRAM with PIM (e.g., an IC with flash memory and another IC with DRAM that includes PIM). The PIM may be realized with at least one AI engine. In example operations, an AI model can be loaded into the DRAM (e.g., from the nonvolatile memory) and then utilized by the AI engine of the PIM. The on-chip memory bandwidth can be relatively fast and consume relatively lower power, including for memory-bound workloads. In example aspects that additionally include a “separate” AI engine in the first package assembly, relatively more compute-bound workloads can be assigned to this AI engine. The utilized memory bandwidth for compute-bound workloads in such situations can still be superior in terms of speed or energy usage as compared to data transfers that extend beyond the package assembly.

The various AI engines can work together in an efficient manner by assigning AI tasks based on access to memory and computing demands of the AI task. For compute-bound AI tasks, such AI tasks may be assigned to the AI engine of the SoC of the second package assembly and/or to the “separate” AI engine of the first package assembly. For memory-bound AI tasks, such AI tasks may be assigned to an AI engine that is realized as a PIM logic unit of the first package assembly and/or to the “separate” AI engine of the first package assembly.

The control functionality for performing an AI procedure may be concentrated at one AI engine or distributed across multiple AI engines. In some cases, a hierarchy of AI engines may be implemented. For example, software (e.g., an application, including an operating system) may assign AI projects to the AI engine of the first package assembly and/or to one or more AI engines that are realized as PIM logic units. Further, in a hierarchical architecture, the software may assign AI projects to the AI engines of the PIM (“PIM AI engines”) based on instructions from the AI accelerator of the SoC. As used herein, a first AI engine that controls a second AI engine or has superior computing resources can be referred to as a “main,” “primary,” “manager,” or “director” AI engine relative the second AI engine. The second AI engine can be referred to as a “satellite,” “secondary,” “tertiary,” “ancillary,” or “worker” AI engine relative to the first AI engine.

Described example implementations enable compute-bound and memory-bound AI tasks to be assigned to AI engines that are relatively more proficient in terms of, e.g., time or energy for performing the AI tasks relative to another AI engine. Further, these example implementations can be tailored to be efficient in terms of size and cost. For instance, newer or different AI tasks can be handled without completely redesigning the main AI engine of the SoC by using “satellite” AI engines, which may be part of a different IC chip and/or a different package assembly. Thus, an area occupied by the SoC package need not be expanded in comparison to previous SoC footprints on a PCB. Further, the one or more AI engines incorporated into a package assembly with nonvolatile memory need not cause the area on the PCB, which is occupied by a nonvolatile memory module, to be appreciably increased.

These and other implementations are described herein and/or depicted in the accompanying drawings.

### Example Environments and Electronic Devices

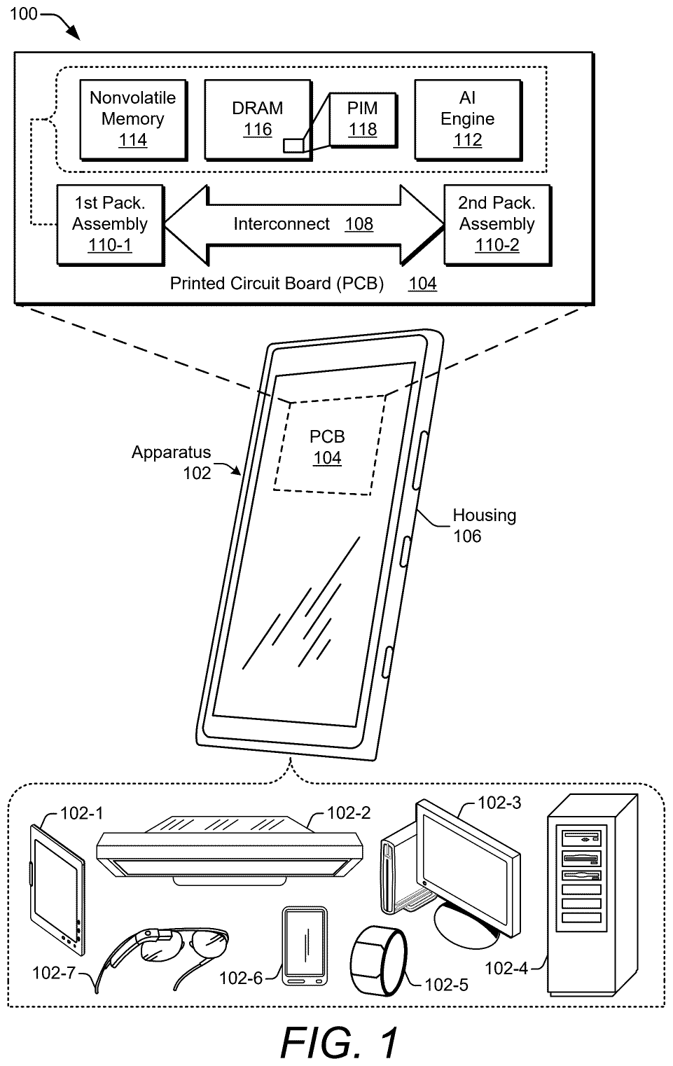

FIG. 1 illustrates, generally at 100, an example apparatus 102 with at least one printed circuit board 104 (PCB 104) that can utilize schemes and techniques for AI engine and memory interoperation as described herein. As shown, a housing 106 of the apparatus 102 encloses the PCB 104 and multiple other components, including some components that are disposed on the PCB 104. For example, a first package assembly 110-1 and a second package assembly 110-2 are mounted on the PCB 104 or otherwise included as part of the PCB 104. As used herein, a PCB 104 can include any structure that is used to support and enable interconnections between components, such as package assemblies, packages, discrete fundamental elements, and so forth. Examples include a “traditional” PCB, a printed wiring board (PWB), a printed circuit assembly (PCA), a circuit card assembly (CCA), a combination thereof, and so forth. Examples of a PCB (or other board or assembly) include a flexible PCB, a rigid PCB, a single or multi-layered PCB, a surface-mounted or through-hole PCB, combinations thereof, and so forth. The PCB 104 may have different form factors or shapes and need not be rectangular.

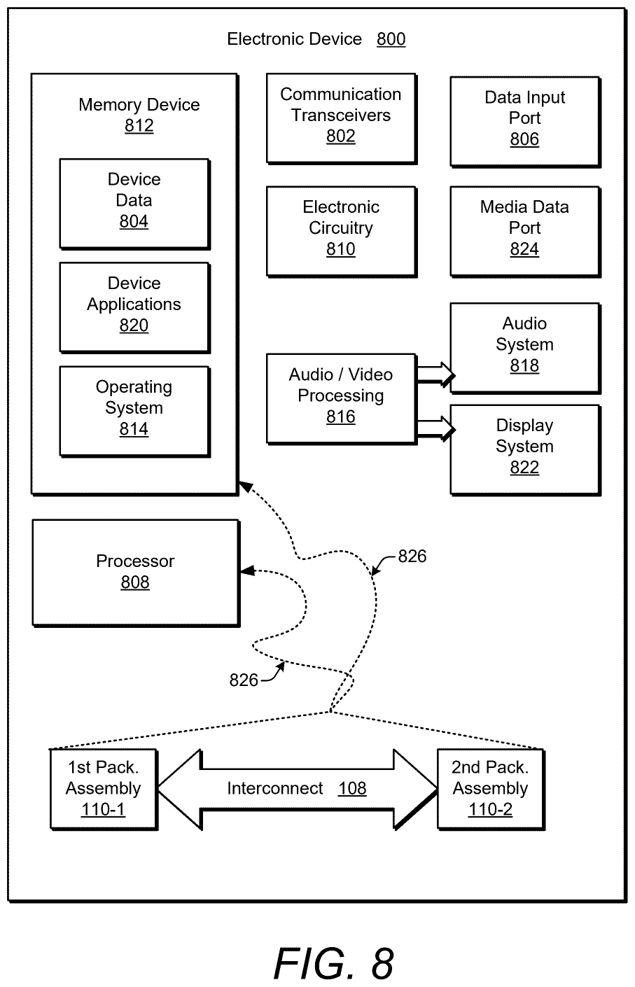

In this example, the apparatus 102 is depicted as a smartphone. The apparatus 102 may, however, be implemented as any suitable computing or other electronic device as described herein. Examples of the apparatus 102 include a mobile electronic device or mobile device, mobile communication device, modem, cellular or mobile phone, mobile station, gaming device, navigation device, media or entertainment device (e.g., a media streamer or gaming controller), laptop computer, desktop computer, tablet computer, smart appliance, vehicle-based electronic system, wearable computing device (e.g., clothing, watch, or reality-altering glasses), Internet of Things (IoTs) device, sensor, stock management device, electronic portion of a machine or piece of equipment (e.g., a vehicle or robot), memory storage device (e.g., a solid-state drive (SSD)), server computer or portion thereof (e.g., a server blade or rack or another part of a datacenter), and the like. Illustrated examples of the apparatus 102 include a tablet device 102-1, a smart television 102-2, a desktop computer 102-3, a server computer 102-4, a smartwatch 102-5, a smartphone (or document reader) 102-6, and intelligent glasses 102-7. An electronic device generally, which can include at least one package assembly 110 as described herein, is described below with reference to FIG. 8 by way of example only.

In example implementations, the PCB 104 can include multiple package assemblies 110-1, 110-2, . . . 110-A (not shown), with “A” representing a positive integer greater than one. Thus, although the depicted examples of a PCB 104 have two package assemblies, a PCB 104 can have more than two package assemblies and/or other components. The apparatus 102, the PCB 104, and/or at least one package assembly 110 (e.g., the first package assembly 110-1) can implement AI engine and memory interoperation as described herein. The PCB 104 can also include at least one interconnect 108 that couples together the first package assembly 110-1 and the second package assembly 110-2.

The first package assembly 110-1 is in electrical communication with the second package assembly 110-2 via the interconnect 108. Thus, the first package assembly 110-1 can transmit information (e.g., data or addresses) over the interconnect 108 to the second package assembly 110-2. Accordingly, the second package assembly 110-2 can receive the information from the first package assembly 110-1 via the interconnect 108. Information transfers can also be effectuated between the multiple package assemblies 110 in the opposite direction using the interconnect 108.

In some implementations, the first package assembly 110-1 can include one or more components. Examples of such components include at least one AI engine 112, at least one instance of nonvolatile memory 114, at least one instance of dynamic random-access memory 116 (DRAM 116). The DRAM 116 can include processor-in-memory 118 (PIM 118), such as at least one processing unit. As described herein, the processing unit of the PIM 118 may be realized with at least one AI engine. Although the first package assembly 110-1 is depicted as including three components of the AI engine 112, the nonvolatile memory 114, and the DRAM 116, it may instead include more, fewer, or different components.

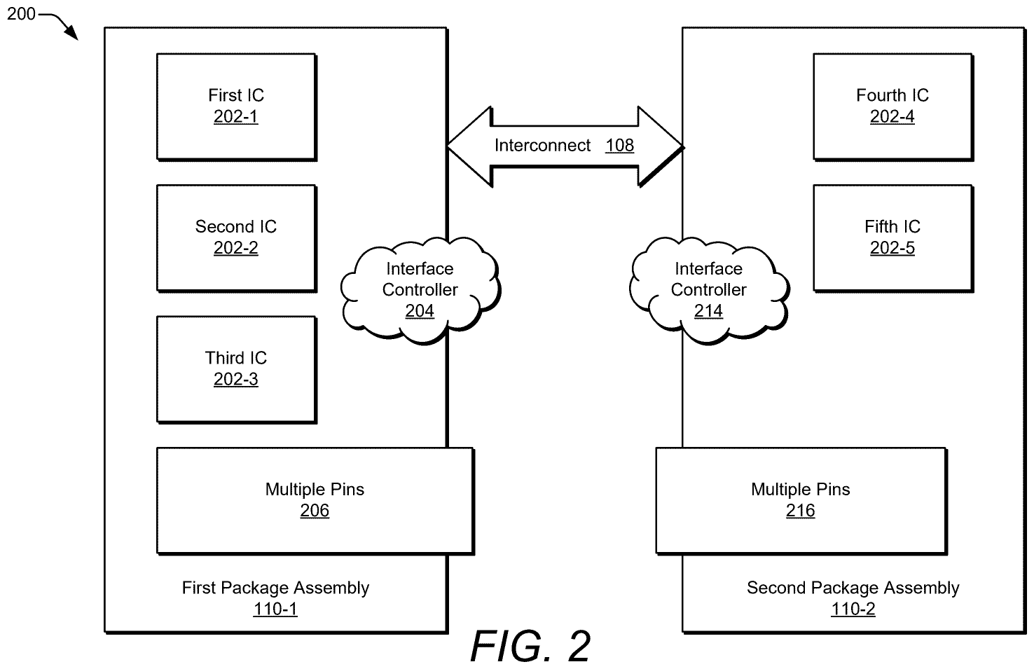

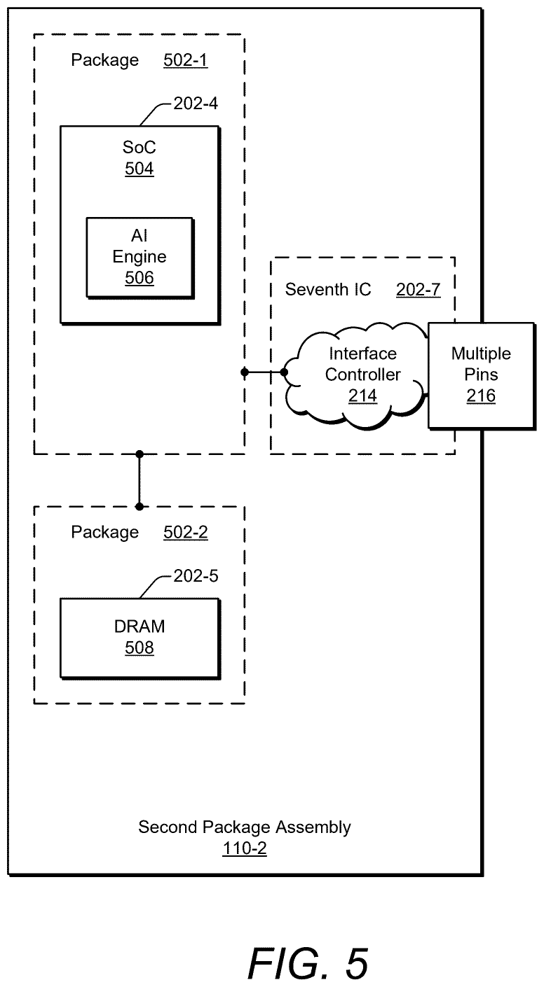

Example implementations of the first package assembly 110-1 are described below with reference to FIGS. 3, 3-1 to 3-4, and 4. Example implementations of the second package assembly 110-2 are described below with reference to FIG. 5. Next, however, example physical realizations of the first package assembly 110-1 and the second package assembly 110-2 are described with reference to FIG. 2.

### Example Apparatuses and Operational Schemes

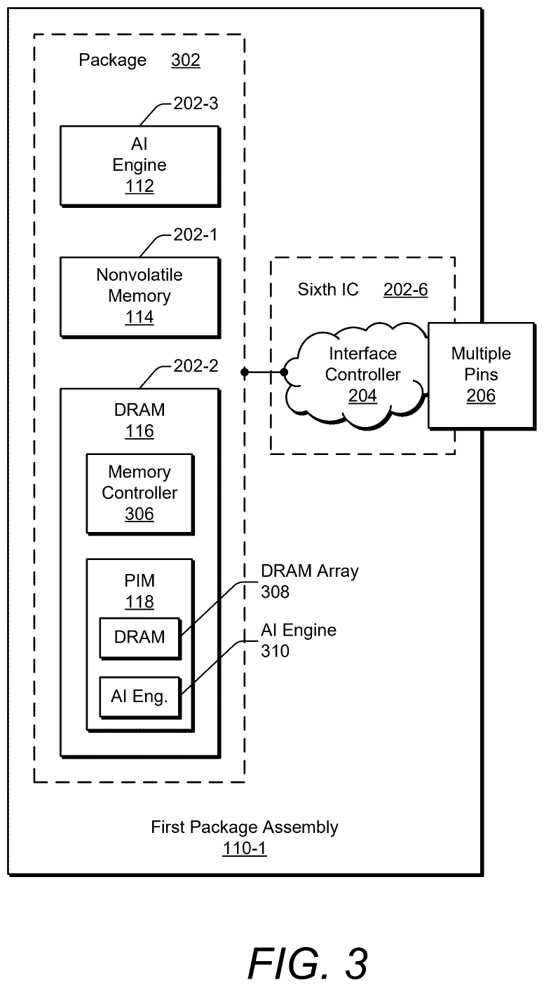

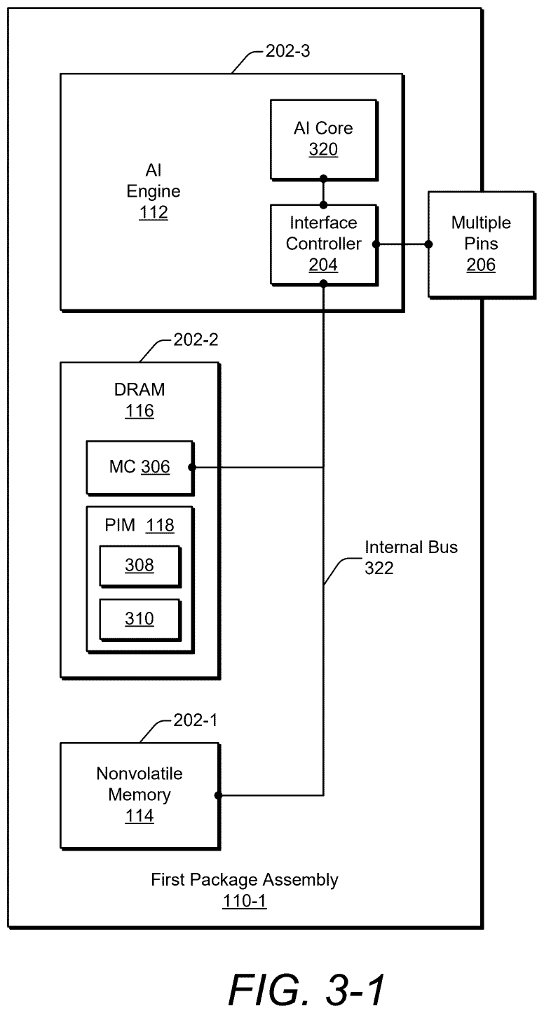

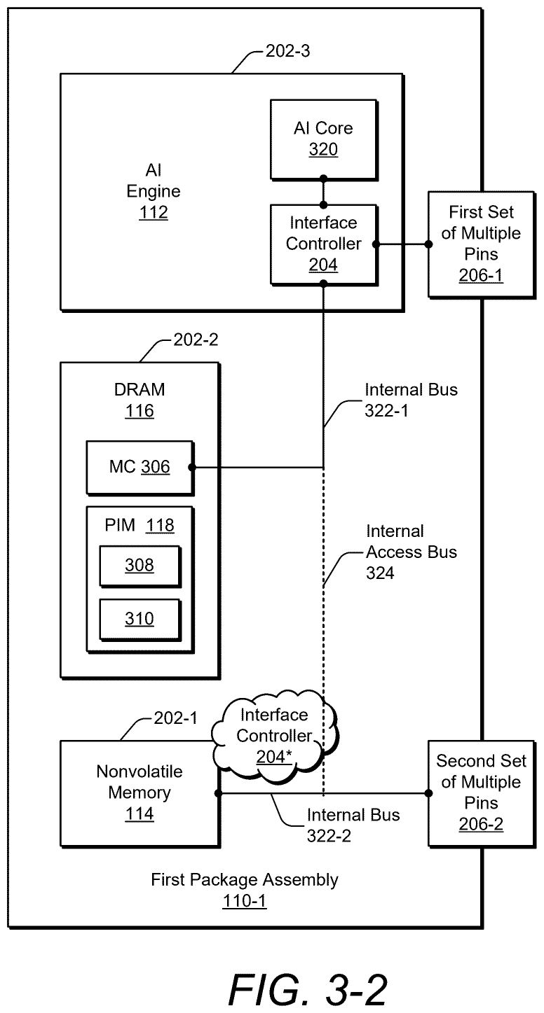

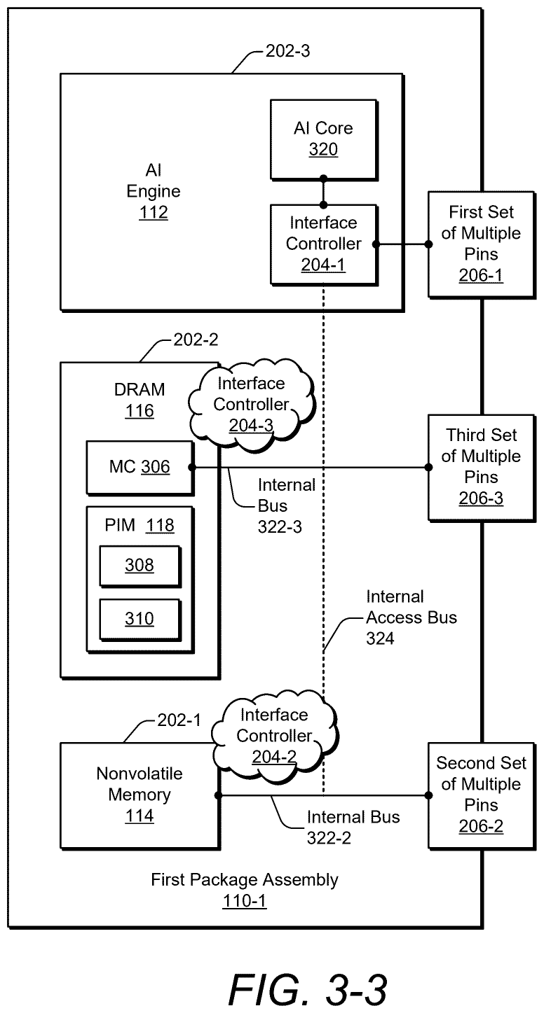

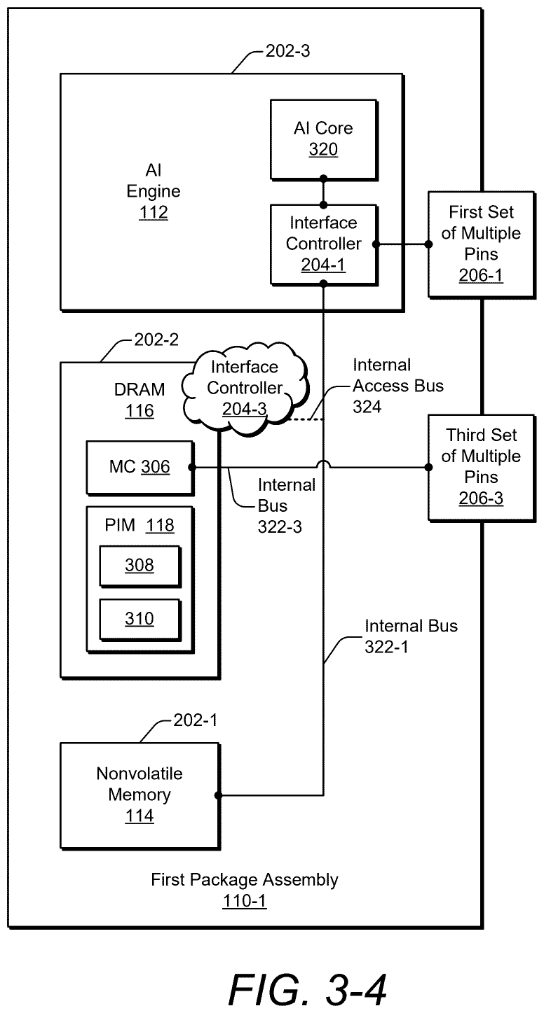

FIG. 2 illustrates, generally at 200, examples of first and second package assemblies, at least one of which may implement AI engine and memory interoperation. As shown, there are multiple integrated circuits (ICs) across the multiple package assemblies 110. These ICs include a first IC 202-1, a second IC 202-2, a third IC 202-3, a fourth IC 202-4, a fifth IC 202-5, a sixth IC 202-6 (e.g., of FIG. 3), . . . , an I^{th} IC 202-I (not shown), with “I” representing a positive integer. The first package assembly 110-1 includes the first IC 202-1, the second IC 202-2, the third IC 202-3, at least one interface controller 204, and at least one set of multiple pins 206. The second package assembly 110-2 includes the fourth IC 202-4, the fifth IC 202-5, at least one interface controller 214, and at least one set of multiple pins 216.

In example implementations, the multiple pins 206 provide electrical communication between components that are internal to the first package assembly 110-1 and components that are external thereto. The interface controller 204 can be coupled between the multiple pins 206 and one or more of the first, second, or third ICs 202-1, 202-2, or 202-3. The interface controller 204 can control, at least partially, the flow of information bidirectionally between one or more of these three ICs and the multiple pins 206. The multiple pins 206 of the first package assembly 110-1 can be coupled to the interconnect 108.

The interconnect 108 can be coupled to the multiple pins 216 of the second package assembly 110-2. The multiple pins 216 provide electrical communication between components that are internal to the second package assembly 110-2 and components that are external thereto. The interface controller 214 can be coupled between the multiple pins 216 and one or more of the fourth or fifth ICs 202-4 or 202-5. The interface controller 214 can control, at least partially, the flow of information bidirectionally between one or more of these two ICs and the multiple pins 206.

In some implementations, each respective IC 202 includes or corresponds to a respective component (e.g., of FIGS. 1 and 3 to 5) that may support AI engine and memory interoperation. For example, for the first package assembly 110-1, the first IC 202-1 can include the nonvolatile memory 114, the second IC 202-2 can include the DRAM 116 (which may include the PIM 118), and the third IC 202-3 can include the AI engine 112. Also, for the second package assembly 110-2, the fourth IC 202-4 can include a system-on-chip (SoC), and the fifth IC 202-5 can include additional or other DRAM.

Various example architectures and interconnections for the first package assembly 110-1 are described below with reference to FIGS. 3, 3-1 to 3-4, and 4. Various example architectures and interconnections for the second package assembly 110-2 are described below with reference to FIG. 5. These example architectures include different quantities of packages per package assembly 110.

FIG. 3 illustrates an example of a first package assembly 110-1 that can include respective ICs for nonvolatile memory 114, DRAM 116 with PIM 118, and an AI engine 112. As illustrated, the first IC 202-1 includes the nonvolatile memory 114, the second IC 202-2 includes the DRAM 116 that incorporates the PIM 118, and the third IC 202-3 includes the AI engine 112. Further, the first package assembly 110-1 includes at least one package 302 and at least the sixth IC 202-6.

In example implementations, the DRAM 116 includes at least one memory controller 306, the PIM 118, at least one DRAM array 308, and at least one AI engine 310. The PIM 118 can include at least one processing unit that is realized as the AI engine 310. In some arrangements, the PIM 118 can include the DRAM array 308 as depicted. In alternative arrangements, the DRAM array 308 can include the AI engine 310 and/or the PIM 118. In still other arrangements, the DRAM array 308 and the PIM 118 can be separate circuitries or separate circuit blocks.

In some cases, the first, second, and third ICs 202-1, 202-2, and 202-3 are packaged together into the package 302. For example, a molding material (not shown), which is internal to the first package assembly 110-1, can at least partially surround the first IC 202-1, the second IC 202-2, and the third IC 202-3. However, the first, second, and/or third ICs 202-1, 202-2, and/or 202-3 may be packaged separately or together in different combinations. For example, the first and third ICs 202-1 and 202-3 can be part of a first package, and the second IC 202-2 can be part of a second package.

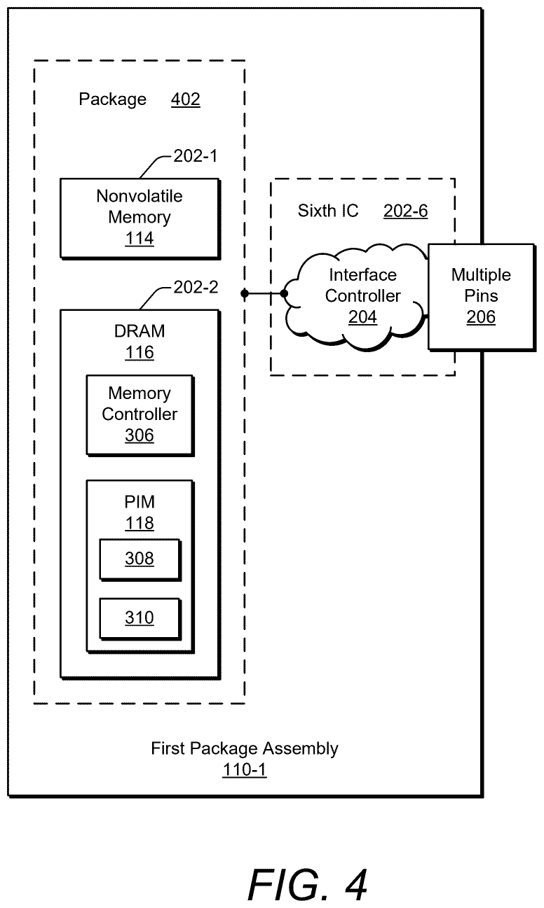

In some cases, the interface controller 204 may be part of an IC, such as the sixth IC 202-6, that is separate from the ICs of the other components. This example architecture is depicted in FIG. 3. The multiple pins 206 provide an interface between the internal components of the first package assembly 110-1 and external components, such as those of the second package assembly 110-2 (e.g., of FIGS. 2 and 4). The interface controller 204 can be coupled between the multiple pins 206 and the components of the package 302. In example operations, the interface controller 204 can route signals to and from the appropriate destinations and origins, respectively, of the first package assembly 110-1.

Implementing the interface controller 204 as a separate IC 202 enables the interface controller 204 to be upgraded to accommodate new or different components without changing other components. Alternatively, the component count can be reduced to save costs by incorporating the interface controller 204 into another component, such as the nonvolatile memory 114. However, doing so results in changing the first IC 202-1 if the interface controller 204 is updated to account for changes to the PIM 118 in the second IC 202-2.

FIGS. 3-1 to 3-4 illustrate examples of different interface and interconnection architectures for the first package assembly. In the example implementations of FIG. 3-1, the first package assembly 110-1 includes a third IC 202-3 that incorporates the interface controller 204. The third IC 202-3 also includes the AI engine 112, which includes an AI core 320 that performs operations to provide AI functionality. Although the interface controller 204 is depicted as being part of the AI engine 112, the interface controller 204 may be logically or physically separate from the circuitry of the AI engine 112.

The interface controller 204 is coupled between the multiple pins 206 and the AI core 320 of the third IC 202-3. The interface controller 204 is also coupled between the multiple pins 206 and the second IC 202-2, such as the memory controller 306 thereof, via an internal bus 322. The interface controller 204 is further coupled between the multiple pins 206 and the first IC 202-1, such as an NVM controller (not shown) thereof, via the internal bus 322. Thus, the interface controller 204 can control the flow of data and other information between the multiple pins 206 and the components of the first and second ICs 202-1 and 202-2.

With the interface controller 204 being part of an IC that provides other functionality (instead of being a separate IC), and with the first package assembly 110-1 having one set of multiple pins 206 in at least some of the example implementations of FIG. 3-1, these example implementations may have some of the lowest costs. However, an external component, such as an SoC, cannot directly access the other components, which may provide higher bandwidth communications. Further, if the PIM 118 of the DRAM 116 of the second IC 202-2 is upgraded in manners that change how external communications are effectuated, the interface controller 204 of the third IC 202-3 may need to be revised, which adds costs to an upgrade cycle.

The example implementations of FIG. 3-2 differ from those of FIG. 3-1 in several ways. For example, the first package assembly 110-1 includes two sets of multiple pins 206: a first set of multiple pins 206-1 and a second set of multiple pins 206-2. Additionally, two ICs may have communication with external components without routing such communications through another IC, and/or the first package assembly 110-1 may include a second interface controller 204.

As shown, the first package assembly 110-1 includes a third IC 202-3 that incorporates an interface controller 204. The third IC 202-3 also includes the AI engine 112, which includes an AI core 320 that performs operations to provide AI functionality. Although the interface controller 204 is depicted as being part of the AI engine 112, the interface controller 204 may be logically or physically separate from the circuitry of the AI engine 112.

The interface controller 204 is coupled between the first set of multiple pins 206-1 and the AI core 320 of the third IC 202-3. The interface controller 204 is also coupled between the first set of multiple pins 206-1 and the second IC 202-2, such as the memory controller 306 thereof, via a first internal bus 322-1. In contrast with FIG. 3-1, the nonvolatile memory 114 of FIG. 3-2 is coupled to a second set of multiple pins 206-2 via a second internal bus 322-2. Another interface controller 204* may facilitate communications between the second set of multiple pins 206-2 and the nonvolatile memory 114. The other interface controller 204* may be integrated with the first IC 202-1 of the nonvolatile memory 114, may be incorporated into one of the other two illustrated ICs, or may be part of another IC (not shown).

Thus, the interface controller 204 can control the flow of data and other information between the first set of multiple pins 206-1 and the second IC 202-2 over the first internal bus 322-1. The other interface controller 204* can control the flow of data and other information between the second set of multiple pins 206-2 and the first IC 202-1 over the second internal bus 322-2. The first package assembly 110-1 can also include at least one internal access bus 324 for communications between internal components that are not being routed to or from a component that is external to the first package assembly 110-1. For example, an AI model stored in the nonvolatile memory 114 can be loaded into the DRAM 116 for execution by the AI engine 310 of the PIM 118.

Compared to the implementations of FIG. 3-1, at least some of the example implementations of FIG. 3-2 may be more costly. First, the set of multiple pins is duplicated. Second, an “additional” other interface controller 204 is included, unless a stock or standard nonvolatile memory 114 “automatically” includes a suitable interface controller. However, an external component, such as an SoC, can directly access at least one other component, which may provide higher bandwidth communications. For example, the SoC can retrieve data from (or store data to) the nonvolatile memory 114 via the second internal bus 322-2 and the second set of multiple pins 206-2 without routing such memory operations through another component, such as those of the third IC 202-3. Including two sets of multiple pins can also enable the use of two interconnects 108 (e.g., of FIGS. 1 and 2) or a wider interconnect 108.

The example implementations of FIG. 3-3 differ from those of FIG. 3-2 in several ways. For example, the first package assembly 110-1 includes three sets of multiple pins 206: a first set of multiple pins 206-1, a second set of multiple pins 206-2, and a third set of multiple pins 206-3. Additionally, three ICs may engage in communications with external components without routing such communications through another IC, and/or the first package assembly 110-1 may include second and third interface controllers 204-2 and 204-3.

As shown, the first package assembly 110-1 includes a third IC 202-3 that incorporates a first interface controller 204-1. The third IC 202-3 also includes the AI engine 112, which includes the AI core 320. Although the first interface controller 204-1 is depicted as being part of the AI engine 112, the first interface controller 204-1 may be logically or physically separate from the circuitry of the AI engine 112.

The first interface controller 204-1 is coupled between the first set of multiple pins 206-1 and the AI core 320 of the third IC 202-3. The second interface controller 204-2 is coupled between the nonvolatile memory 114 and the second set of multiple pins 206-2 via a second internal bus 322-2. The third interface controller 204-3 is coupled between the DRAM 116 and the third set of multiple pins 206-3 via a third internal bus 322-3. The first, second, and third interface controllers 204-1, 204-2, and 204-3 can respectively facilitate communications between the first set of multiple pins 206-1, the second set of multiple pins 206-2, and the third set of multiple pins 206-3 and the components of the third, first, and second ICs 202-3, 202-1, and 202-2. The second and third interface controllers 204-2 and 204-3 may be integrated with their respective first and second ICs 202-1 and 202-2, may be incorporated into a different illustrated IC, or may be part of another IC (not shown) of the first package assembly 110-1.

The first package assembly 110-1 can also include an internal access bus 324 for communications between internal components that are not being routed to or from a component that is external to the first package assembly 110-1. The internal access bus 324 may be a shared bus for more than two components, separate respective internal access buses between respective pairs of components, or some combination thereof. As compared to the example implementations of FIG. 3-2, those of FIG. 3-3 offer still more communication flexibility and bandwidth at still more potential costs based on the addition of another set of multiple pins and another interface controller.

The example implementations of FIG. 3-4 share some aspects with those of FIG. 3-2 and some aspects of FIG. 3-3. For example, the first package assembly 110-1 includes two sets of multiple pins 206: a first set of multiple pins 206-1 and a third set of multiple pins 206-3. Additionally, two ICs may engage in communications with external components without routing such communications through another IC, and at least one component accesses external components through another internal component. Specifically, the AI engine 112 can communicate with external components via the first set of multiple pins 206-1 under the control of a first interface controller 204-1. The DRAM 116 can be in communication with external components via the third set of multiple pins 206-3 under the control of a third interface controller 204-3. Accordingly, the example implementations of FIG. 3-4 share some of the relative advantages and disadvantages with those of FIG. 3-2, but an external component, such as an SoC, can access the DRAM 116 (instead of the nonvolatile memory 114) without routing communications through another IC.

FIG. 4 illustrates another example of a first package assembly 110-1 that can include respective ICs 202-2 and 202-3 for nonvolatile memory 114 and DRAM 116 with PIM 118. Thus, for the example implementations of FIG. 4, the first package assembly 110-1 omits or lacks a separate IC devoted to AI. For instance, the first package assembly 110-1 can omit a third IC 202-3 that includes an AI engine 112. The first IC 202-1 and the second IC 202-2 can be combined into at least one package 402, which may comprise a single package or multiple packages. The interface controller 204 can be part of a separate IC (e.g., a sixth IC 202-6) or part of the first or second ICs 202-1 and 202-2. Relative to the example implementations of FIG. 3, those of FIG. 4 may have a lower cost but sacrifice some AI computing horsepower.

FIG. 5 illustrates an example of a second package assembly 110-2 that can include respective ICs 202-4 and 202-5 for a system-on-chip 504 (SoC 504) and DRAM 508. In example implementations, the fourth IC 202-4 includes the SoC 504. The SoC 504 can also include at least one AI engine 506. In some cases, the AI engine 506 of the SoC 504 is more powerful than the AI engine 112 of the first package assembly 110-1 (e.g., of FIG. 3), and the AI engine 112 is more powerful than the AI engine 310 of the PIM 118 of the DRAM 116 of the first package assembly 110-1. With this hierarchy, more compute-bound AI tasks can be assigned to a more powerful AI engine (e.g., the AI engine 506 and then the AI engine 112), and more memory-bound AI tasks can be assigned to the less powerful (but perhaps more numerous) AI engine(s) that are closer to the data (e.g., the AI engine 310).

The fifth IC 202-5 includes the DRAM 508. In some implementations, the fourth IC 202-4 is part of a first package 502-1, and the fifth IC 202-5 is part of a second package 502-2. In at least some of such cases, these two packages can be combined into a package-on-package (POP) arrangement as at least part of the second package assembly 110-2. The interface controller 214 is coupled between the multiple pins 216 and at least one package 502. As shown, the interface controller 214 is coupled between the multiple pins 216 and the SoC 504. In some cases, the interface controller 214 can be part of the first package 502-1, including by being part of the SoC 202-4 or part of a redistribution layer. In other cases, the interface controller 214 can be part of a seventh IC 202-7 (as depicted) or the second package 502-2.

Having generally described schemes, techniques, and hardware for implementing AI engine and memory interoperation, this discussion now turns to example methods.

### Example Methods

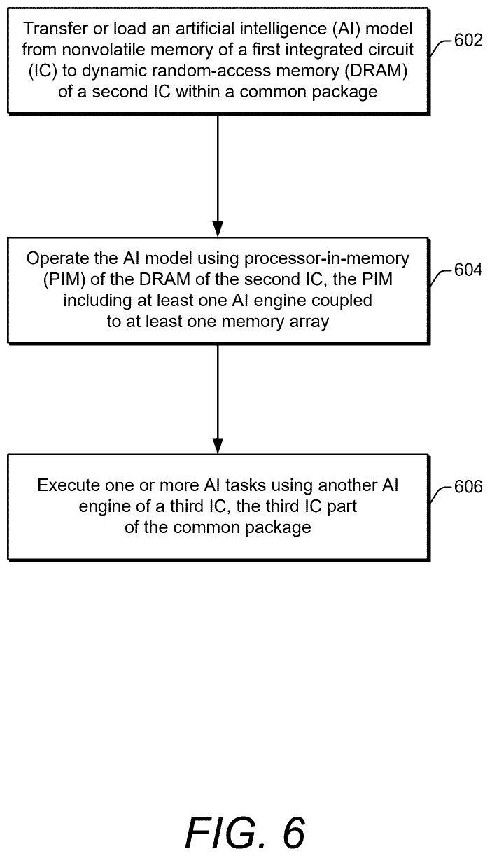

FIG. 6 is a flow diagram illustrating an example process 600 for implementing AI engine and memory interoperation with respect to using a semiconductor package assembly. The process 600 includes three operations 602-606.

At block 602, an artificial intelligence (AI) model is transferred or loaded from nonvolatile memory of a first integrated circuit (IC) to dynamic random-access memory (DRAM) of a second IC within a common package. For example, an AI controller can transfer or load an AI model from nonvolatile memory 114 of a first IC 202-1 to DRAM 116 of a second IC 202-2 within a common package 302. For instance, an AI controller of the common package or an AI controller that is disposed in a second package may direct the transfer of the AI model. If the AI controller is in a second package, the AI controller may also be in a different package assembly 110, such as one with an SoC 504.

At block 604, the AI model is operated using processor-in-memory (PIM) of the DRAM of the second IC, with the PIM including at least one AI engine coupled to at least one memory array. For example, the AI controller can operate the AI model using processor-in-memory 118 (PIM 118) of the DRAM 116 of the second IC 202-2. Here, the PIM 118 can include at least one AI engine 310 that is coupled to at least one memory array 308. In some cases, the AI controller is the same AI controller or a different AI controller as the one that directs the AI model transfer. If the same AI controller, the AI controller can be localized at one IC chip or distributed across multiple IC chips. Thus, the AI controller can be integrated with the AI engine 310 or the PIM 118 or can be part of a different IC chip.

At block 606, one or more AI tasks are executed using another AI engine of a third IC, with the third IC part of the common package. For example, an AI engine 112 of a third IC 202-3 can execute one or more AI tasks, with the third IC 202-3 part of the common package 302. To do so, the same or a different AI controller can assign the one or more AI tasks to the AI engine 112. The AI controller, or portion thereof, can also or additionally be included in the third IC 202-3. To balance compute-bound versus memory-bound AI tasks, the AI controller can assign the one or more AI tasks to the AI engine 112 if these AI tasks are relatively more compute-bound and assign one or more other AI tasks that are relatively more memory-bound to the AI engine 310 of the PIM 118.

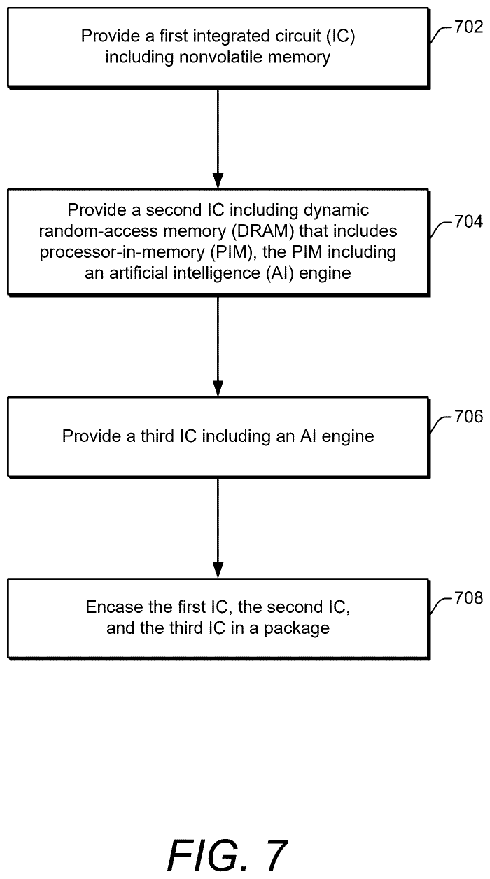

FIG. 7 is a flow diagram illustrating an example process 700 for implementing AI engine and memory interoperation with respect to manufacturing a semiconductor package assembly. The process 700 includes four operations 702-708.

At block 702, a first integrated circuit (IC) including nonvolatile memory is provided. For example, a first IC 202-1 including nonvolatile memory 114 can be provided. The nonvolatile memory 114 may be realized using, for instance, flash memory.

At block 704, a second IC including dynamic random-access memory (DRAM) that includes processor-in-memory (PIM), with the PIM comprising an artificial intelligence (AI) engine, can be provided. For example, a second IC 202-2 including DRAM 116 that includes processor-in-memory 118 (PIM 118), with the PIM 118 realizing an artificial intelligence (AI) engine 310, can be provided. In some cases, the PIM 118 may include DRAM 308 and the AI engine 310. In other cases, the DRAM 308 may include the PIM 118 with multiple AI processing units to realize the AI engine 310.

At block 706, a third IC including an AI engine is provided. For example, a third IC 202-3 including an AI engine 112 can be provided. Here, the AI engine 112 may be more powerful at executing AI tasks than the AI engine 310 to facilitate a hierarchical assignment of AI tasks to provide efficient AI processing in terms of power or bandwidth.

At block 708, the first IC, the second IC, and the third IC are encased in a package. For example, a manufacturing tool or fabrication equipment can encase the first IC 202-1, the second IC 202-2, and the third IC 202-3 in a package 302. Thus, the package 302 may realize all or part of a first package assembly 110-1. The first package assembly 110-1 may include one or more interfaces as represented by one or more sets of multiple pins 206. At least one of these interfaces may comport with a Universal Flash Storage (UFS) interface. Additionally or alternatively, at least one interface may comport with a DRAM standard, a customized bus operation standard, and so forth.

Aspects of these methods may be implemented in, for example, hardware (e.g., fixed logic circuitry, a controller, a finite state machine, or a processor in conjunction with a memory), firmware, software, or some combination thereof. The methods may be realized to produce one or more of the apparatuses or components shown in FIGS. 1 to 5 and 8, which components may be further divided, combined, and so on. The devices and components of these figures generally represent hardware, such as electronic devices, PCBs, packaged modules, IC chips, components, or circuits; firmware; software; or a combination thereof. Thus, these figures illustrate some of the many possible systems or apparatuses capable of being produced or employed using the described methods.

For the methods described herein and the associated flow chart(s) and/or flow diagram(s), the orders in which operations are shown and/or described are not intended to be construed as a limitation. Instead, any number or combination of the described method operations can be combined in any order to implement a given method or an alternative method, including by combining operations from different ones of the flow chart(s) and flow diagram(s) and the earlier-described schemes and techniques into one or more methods. Operations may also be omitted from or added to the described methods. Further, described operations can be implemented in fully or partially overlapping manners.

### Additional Example Apparatuses and Electronic Devices

FIG. 8 illustrates various components of an example electronic device 800 that can implement and/or include hardware for AI engine and memory interoperation in accordance with one or more described aspects. The electronic device 800 may be implemented as any one or combination of a fixed, mobile, stand-alone, or embedded device or in any form of a consumer, computer, portable, user, server, communication, phone, navigation, gaming, audio, camera, messaging, media playback, and/or other type of electronic device 800, such as the smartphone that is depicted in FIG. 1 as an example of the apparatus 102. One or more of the illustrated components may be realized as discrete components or as integrated components on at least one integrated circuit chip of the electronic device 800 or separately or jointly in one or more packages of the electronic device 800.

The electronic device 800 can include one or more communication transceivers 802 that enable wired and/or wireless communication of device data 804, such as received data, transmitted data, or other information identified above. Example communication transceivers 802 include near-field communication (NFC) transceivers, wireless personal area network (PAN) (WPAN) radios compliant with various IEEE 802.15 (Bluetooth®) standards, wireless local area network (LAN) (WLAN) radios compliant with any of the various IEEE 802.11 (Wi-Fi®) standards, wireless wide area network (WAN) (WWAN) radios (e.g., those that are 3GPP-compliant) for cellular telephony, wireless metropolitan area network (MAN) (WMAN) radios compliant with various IEEE 802.16 (WiMAX™) standards, infrared (IR) transceivers compliant with an Infrared Data Association (IrDA) protocol, and wired local area network (LAN) (WLAN) Ethernet transceivers.

The electronic device 800 may also include one or more data input ports 806 via which any type of data, media content, and/or other inputs can be received, such as user-selectable inputs, messages, applications, music, television content, recorded video content, and any other type of audio, video, and/or image data received from any content and/or data source, including a sensor like a microphone or a camera. The data input ports 806 may include USB ports, coaxial cable ports, fiber optic ports for optical fiber interconnects or cabling, and other serial or parallel connectors (including internal connectors) for flash memory, DVDs, CDs, and the like. These data input ports 806 may be used to couple the electronic device to components, peripherals, or accessories such as keyboards, microphones, cameras, or other sensors.

The electronic device 800 of this example includes at least one processor 808 (e.g., any one or more of application processors, microprocessors, digital-signal processors (DSPs), controllers, and the like), which can include a combined processor and memory system (e.g., implemented as part of an SoC), that processes (e.g., executes) computer-executable instructions to control operation of the device. The processor 808 may be implemented as an application processor, embedded controller, microcontroller, security processor, artificial intelligence (AI) accelerator, and the like. Generally, a processor or processing system may be implemented at least partially in hardware, which can include components of an integrated circuit or on-chip system, a digital signal processor (DSP), an application-specific integrated circuit (ASIC), a field programmable gate array (FPGA), a complex programmable logic device (CPLD), and other implementations in silicon and/or other materials.

Alternatively or additionally, the electronic device 800 can be implemented with any one or combination of electronic circuitry, which may include software, hardware, firmware, or fixed logic circuitry that is implemented in connection with processing and control circuits, which are generally indicated at 810 (as electronic circuitry 810). This electronic circuitry 810 can implement executable or hardware-based modules (not shown in FIG. 8), such as through processing/computer-executable instructions stored on computer-readable media, through logic circuitry and/or hardware (e.g., such as an FPGA), and so forth.

The electronic device 800 can include a system bus, interconnect, crossbar, data transfer system, switch fabric, or other communication fabric that couples the various components within the device (e.g., the illustrated interconnect 108). A system bus or interconnect can include any one or a combination of different bus structures, such as a memory bus or memory controller, a peripheral bus, a universal serial bus (USB), and/or a processor or local bus that utilizes any of a variety of bus architectures.

The electronic device 800 also includes one or more memory devices 812 that enable data storage, examples of which include random-access memory (RAM), non-volatile memory (e.g., read-only memory (ROM), flash memory, EPROM, and EEPROM), and a disk storage device. Thus, the memory device(s) 812 can be distributed across different logical storage levels of a system as well as at different physical components. The memory device(s) 812 provide data storage mechanisms to store the device data 804, other types of code and/or data, and various device applications 820 (e.g., software applications or programs). For example, an operating system 814 can be maintained as software instructions within the memory device 812 and executed by the processor 808.

In some implementations, the electronic device 800 also includes an audio and/or video processing system 816 that processes audio and/or video data and/or that passes through the audio and/or video data to an audio system 818 and/or to a display system 822 (e.g., a video buffer or a screen of a smartphone or camera). The audio system 818 and/or the display system 822 may include any devices that process, display, and/or otherwise render audio, video, display, and/or image data. Display data and audio signals can be communicated to an audio component and/or to a display component via an RF (radio-frequency) link, an S-video link, an HDMI (high-definition multimedia interface) link, a composite video link, a component video link, a DVI (digital video interface) link, an analog audio connection, a video bus, or another similar communication link, such as a media data port 824. In some implementations, the audio system 818 and/or the display system 822 are external or separate components of the electronic device 800. Alternatively, the display system 822, for example, can be an integrated component of the example electronic device 800, such as part of an integrated touch interface.

The electronic device 800 of FIG. 8 illustrates example implementations of the apparatus 102 of FIG. 1, of an apparatus that may include a package assembly 110 of any of the FIGS. 2 to 5, or some combination thereof. Accordingly, one of the components in FIG. 8 may include or be part of at least one package assembly 110, such as a first package assembly 110-1 or a second package assembly 110-2. For example, as indicated by the arrows 826, a given package assembly 110 may include at least one processor 808 or at least one memory device 812. Thus, a given package assembly 110 may include a processor 808 and a memory device 812 in accordance with a permitted herein, but optional, interpretation of the word “or” as connoting an “inclusive or” relationship. The operating system 814 or an application (e.g., of the device applications 820) may separate an AI project into different AI tasks and assign the AI tasks to different AI engines based on power efficiency, bandwidth efficiency, time to completion, compute-bound status, memory-bound status, a combination thereof, and so forth.

### Example Aspects and Implementations for AI Engine and Memory Interoperation

In the following, some examples, example aspects, and implementations are described:

Example aspect 1: An apparatus comprising: a package assembly comprising: a first integrated circuit (IC) including nonvolatile memory; a second IC including dynamic random-access memory (DRAM) that includes processor-in-memory (PIM), the PIM comprising an artificial intelligence (AI) engine; a third IC including an AI engine; and multiple pins coupled to the first IC, the second IC, and the third IC, the multiple pins exposed to an exterior of the package assembly.

Example aspect 2: The apparatus of example aspect 1, wherein: the package assembly further comprises an interior including a molding material that at least partially surrounds the first IC, the second IC, and the third IC; and the multiple pins are disposed partially within the molding material of the interior of the package assembly.

Example aspect 3: The apparatus of example aspect 1 or any of the other preceding example aspects, wherein at least one of: the nonvolatile memory of the first IC comprises flash memory; or the DRAM of the second IC comprises double data-rate (DDR) DRAM.

Example aspect 4: The apparatus of example aspect 1 or any of the other preceding example aspects, wherein the AI engine of the third IC comprises at least one of: a machine learning (ML) engine; a processor configured to accelerate matrix operations; or a tensor processing unit.

Example aspect 5: The apparatus of example aspect 1 or any of the other preceding example aspects, wherein the AI engine of the PIM of the second IC comprises at least one of: a machine learning (ML) engine; a processor configured to accelerate matrix operations; or a tensor processing unit.

Example aspect 6: The apparatus of example aspect 1 or any of the other preceding example aspects, wherein: the PIM comprises multiple AI engines and multiple memory arrays; and each respective AI engine of the multiple AI engines is coupled to and corresponds to a respective memory array of the multiple memory arrays.

Example aspect 7: The apparatus of example aspect 1 or any of the other preceding example aspects, wherein: the package assembly comprises interface controller configured to facilitate communications between the package assembly and another package assembly.

Example aspect 8: The apparatus of example aspect 7 or any of the other preceding example aspects, wherein: the third IC includes the interface controller; the interface controller is coupled to the AI engine of the third IC; and the interface controller is configured to control, at least partially, communications between the AI engine of the third IC and the other package assembly.

Example aspect 9: The apparatus of example aspect 8 or any of the other preceding example aspects, wherein: the interface controller is coupled to the nonvolatile memory of the first IC; and the interface controller is configured to control, at least partially, communications between the nonvolatile memory of the first IC and the other package assembly.

Example aspect 10: The apparatus of example aspect 8 or any of the other preceding example aspects, wherein: the interface controller is coupled to the DRAM of the second IC; and the interface controller is configured to control, at least partially, communications between the DRAM of the second IC and the other package assembly.

Example aspect 11: The apparatus of example aspect 8 or any of the other preceding example aspects, wherein: the interface controller is coupled to the DRAM of the second IC; and the interface controller is configured to control, at least partially, communications between the DRAM of the second IC and the AI engine of the third IC.

Example aspect 12: The apparatus of example aspect 11 or any of the other preceding example aspects, wherein: the interface controller is configured to control, at least partially, communications between the AI engine of the PIM of the second IC and the AI engine of the third IC.

Example aspect 13: The apparatus of example aspect 7 or any of the other preceding example aspects, wherein: the interface controller is separate from the first IC, the second IC, and the third IC; the interface controller is coupled to the AI engine of the third IC and the nonvolatile memory of the first IC; the interface controller is configured to control, at least partially, communications between the nonvolatile memory of the first IC and the other package assembly; and the interface controller is configured to control, at least partially, communications between the AI engine of the third IC and the other package assembly.

Example aspect 14: The apparatus of example aspect 13 or any of the other preceding example aspects, wherein: the interface controller is configured to control, at least partially, communications between the nonvolatile memory of the first IC and the AI engine of the third IC.

Example aspect 15: The apparatus of example aspect 1 or any of the other preceding example aspects, wherein: the multiple pins comprise a first set of pins and a second set of pins; the first set of pins is coupled between the AI engine of the third IC and the exterior of the package assembly, the package assembly configured to route incoming information from the first set of pins to the third IC before reaching the first IC or the second IC; and the second set of pins is coupled between the nonvolatile memory of the first IC and the exterior of the package assembly, the package assembly configured to route incoming information from the second set of pins to the first IC before reaching the second IC or the third IC.

Example aspect 16: The apparatus of example aspect 1 or any of the other preceding example aspects, wherein: the AI engine of the third IC comprises a main AI engine; and the AI engine of the PIM of the second IC comprises an ancillary AI engine relative to the main AI engine.

Example aspect 17: The apparatus of example aspect 16 or any of the other preceding example aspects, wherein: the AI engine of the third IC is configured to assign one or more tasks to the ancillary AI engine for the ancillary AI engine to perform the one or more tasks; and the AI engine of the third IC is configured to assign at least one task to the main AI engine for the main AI engine to perform the task.

Example aspect 18: The apparatus of example aspect 17 or any of the other preceding example aspects, wherein: the main AI engine is configured to assign the one or more tasks to the ancillary AI engine and is configured to retain the task for the main AI engine to perform the task.

Example aspect 19: The apparatus of example aspect 1 or any of the other preceding example aspects, wherein: an application executing on the apparatus is configured to assign one or more tasks to the AI engine of the PIM of the second IC and is configured to assign at least one task to the AI engine of the third IC.

Example aspect 20: The apparatus of example aspect 19 or any of the other preceding example aspects, wherein: the one or more tasks corresponds to at least one relatively memory-bound AI task; and the task corresponds to at least one relatively compute-bound AI task.

Example aspect 21: The apparatus of example aspect 20 or any of the other preceding example aspects, wherein: the relatively memory-bound AI task comprises content generation based on a large-language model (LLM); and the relatively compute-bound AI task comprises image modification.

Example aspect 22: The apparatus of example aspect 1 or any of the other preceding example aspects, wherein: the apparatus comprises a mobile device.

Example aspect 23: The apparatus of example aspect 1 or any of the other preceding example aspects, wherein: the first IC, the second IC, and the third IC are part of a same package of the package assembly.

Example aspect 24: The apparatus of example aspect 23 or any of the other preceding example aspects, wherein: the same package comports with at least one micro multi-chip package (uMCP) specification.

Example aspect 25: The apparatus of example aspect 23 or any of the other preceding example aspects, wherein: the same package has dimensions of approximately 11.5 millimeters (mm) by approximately 13 mm (e.g., within 10%, 5%, or even 1% of these measurements or otherwise within industry-typical deviations for package dimensions).

Example aspect 26: The apparatus of example aspect 1 or any of the other preceding example aspects, wherein: the package assembly comprises a first package assembly; and the apparatus further comprises a second package assembly coupled to the first package assembly, the second package assembly comprising a fourth IC.

Example aspect 27: The apparatus of example aspect 26 or any of the other preceding example aspects, wherein: the fourth IC comprises a system-on-chip (SoC).

Example aspect 28: The apparatus of example aspect 27 or any of the other preceding example aspects, wherein: the SoC comprises an AI engine.

Example aspect 29: The apparatus of example aspect 28 or any of the other preceding example aspects, wherein: the AI engine of the SoC comprises a main AI engine; and the AI engine of the third IC comprises an ancillary AI engine relative to the main AI engine.

Example aspect 30: The apparatus of example aspect 29 or any of the other preceding example aspects, wherein: the SoC is configured to assign one or more tasks to the ancillary AI engine for the ancillary AI engine to perform the one or more tasks.

Example aspect 31: The apparatus of example aspect 30 or any of the other preceding example aspects, wherein: the SoC is configured to assign at least one task to the main AI engine for the main AI engine to perform the task.

Example aspect 32: The apparatus of example aspect 31 or any of the other preceding example aspects, wherein: the main AI engine is configured to assign the one or more tasks to the ancillary AI engine and is configured to retain the task for the main AI engine to perform the task.

Example aspect 33: The apparatus of example aspect 31 or any of the other preceding example aspects, wherein: the one or more tasks corresponds to at least one relatively memory-bound AI task; and the task corresponds to at least one relatively compute-bound AI task.

Example aspect 34: The apparatus of example aspect 33 or any of the other preceding example aspects, wherein: the relatively memory-bound AI task comprises content generation based on a large-language model (LLM); and the relatively compute-bound AI task comprises image modification.

Example aspect 35: The apparatus of example aspect 27 or any of the other preceding example aspects, wherein: the second package assembly comprises a fifth IC; and the fifth IC comprises DRAM.

Example aspect 36: The apparatus of example aspect 35 or any of the other preceding example aspects, wherein: the second package assembly comprises a package-on-package (POP) assembly with a first package including the fourth IC disposed between a second package including the fifth IC and multiple pins of the PoP assembly.

Example aspect 37: The apparatus of example aspect 35 or any of the other preceding example aspects, wherein: the DRAM of the fifth IC comprises double data-rate (DDR) DRAM.

Example aspect 38: The apparatus of example aspect 26 or any of the other preceding example aspects, further comprising: at least one printed circuit board (PCB), wherein: the first package assembly is mounted to the PCB; and the second package assembly is mounted to the PCB.

Example aspect 39: The apparatus of example aspect 38 or any of the other preceding example aspects, wherein: the PCB comprises at least one interconnect; and the first package assembly is coupled to the second package assembly via the interconnect.

Example aspect 40: The apparatus of example aspect 38 or any of the other preceding example aspects, further comprising: a housing, wherein the housing encloses the PCB, the first package assembly, and the second package assembly.

Example aspect 41: The apparatus of example aspect 40 or any of the other preceding example aspects, wherein: the apparatus comprises a mobile device.

Example aspect 42: An apparatus comprising: a package assembly comprising: a first integrated circuit (IC) including nonvolatile memory; a second IC including dynamic random-access memory (DRAM) that includes processor-in-memory (PIM) circuitry, the PIM circuitry comprising an artificial intelligence (AI) engine; and multiple pins coupled to the first IC and the second IC, the multiple pins exposed to an exterior of the package assembly.

Example aspect 43: A method comprising: transferring or loading an artificial intelligence (AI) model from nonvolatile memory of a first integrated circuit (IC) to dynamic random-access memory (DRAM) of a second IC within a common package; operating the AI model using processor-in-memory (PIM) of the DRAM of the second IC, the PIM including at least one AI engine coupled to at least one memory array; and executing one or more AI tasks using another AI engine of a third IC, the third IC part of the common package.

Example aspect 44: A method comprising: providing a first integrated circuit (IC) including nonvolatile memory; providing a second IC including dynamic random-access memory (DRAM) that includes processor-in-memory (PIM), the PIM comprising an artificial intelligence (AI) engine; providing a third IC including an AI engine; and encasing the first IC, the second IC, and the third IC in a package.

Example aspect 45: The method of example aspect 44 or any of the other preceding example aspects, further comprising: coupling the first IC, the second IC, and the third IC directly or indirectly to multiple pins; and exposing the multiple pins to an exterior of the package.

Example aspect 46: The method of example aspect 45 or any of the other preceding example aspects, further comprising: incorporating at least one interface controller between the multiple pins and at least one of the first IC, the second IC, or the third IC.

Example aspect 47: An apparatus comprising: a package assembly comprising: a first integrated circuit (IC) including nonvolatile memory; a second IC including dynamic random-access memory (DRAM) that includes processor-in-memory (PIM), the PIM comprising a first artificial intelligence (AI) engine; a third IC including a second AI engine; and multiple pins coupled to the first IC, the second IC, and the third IC, the multiple pins exposed to an exterior of the package assembly.

Example aspect 48: A method comprising: providing a first integrated circuit (IC) including nonvolatile memory; providing a second IC including dynamic random-access memory (DRAM) that includes processor-in-memory (PIM), the PIM comprising a first artificial intelligence (AI) engine; providing a third IC including a second AI engine; and encasing the first IC, the second IC, and the third IC in a package.

Features described in the context of one example aspect (e.g., a method or an apparatus) may be used in combination with other example aspects (e.g., an apparatus or a method, respectively, or a different method or a different apparatus).

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing AI engine and memory interoperation have been described in language specific to certain features and/or methods, the subject of the appended claims is not necessarily limited to the specific features or methods described. Rather, the specific features and methods are disclosed as example implementations for realizing AI engine and memory interoperation.

What is claimed is:

1. An apparatus comprising:
a package assembly comprising:
a first integrated circuit (IC) including nonvolatile memory;
a second IC including dynamic random-access memory (DRAM) that includes processor-in-memory (PIM), the PIM comprising an artificial intelligence (AI) engine;
a third IC including an AI engine; and
multiple pins coupled to the first IC, the second IC, and the third IC, the multiple pins exposed to an exterior of the package assembly.

2. The apparatus of claim 1, wherein:
the package assembly further comprises an interior including a molding material that at least partially surrounds the first IC, the second IC, and the third IC; and
the multiple pins are disposed partially within the molding material of the interior of the package assembly.

3. The apparatus of claim 1, wherein the AI engine of the PIM of the second IC comprises at least one of:
a machine learning (ML) engine;
a processor configured to accelerate matrix operations; or
a tensor processing unit.

4. The apparatus of claim 1, wherein:
the PIM comprises multiple AI engines and multiple memory arrays; and
each respective AI engine of the multiple AI engines is coupled to and corresponds to a respective memory array of the multiple memory arrays.

5. The apparatus of claim 1, wherein:
the package assembly comprises an interface controller configured to facilitate communications between the package assembly and another package assembly.

6. The apparatus of claim 5, wherein:
the third IC includes the interface controller;
the interface controller is coupled to the AI engine of the third IC; and
the interface controller is configured to control, at least partially, communications between the AI engine of the third IC and the other package assembly.

7. The apparatus of claim 6, wherein:
the interface controller is coupled to the DRAM of the second IC; and
the interface controller is configured to control, at least partially, communications between the DRAM of the second IC and the other package assembly.

8. The apparatus of claim 6, wherein:
the interface controller is coupled to the DRAM of the second IC; and
the interface controller is configured to control, at least partially, communications between the DRAM of the second IC and the AI engine of the third IC.

9. The apparatus of claim 5, wherein:
the interface controller is separate from the first IC, the second IC, and the third IC;
the interface controller is coupled to the AI engine of the third IC and the nonvolatile memory of the first IC;
the interface controller is configured to control, at least partially, communications between the nonvolatile memory of the first IC and the other package assembly; and
the interface controller is configured to control, at least partially, communications between the AI engine of the third IC and the other package assembly.

10. The apparatus of claim 1, wherein:
the multiple pins comprise a first set of pins and a second set of pins;
the first set of pins is coupled between the AI engine of the third IC and the exterior of the package assembly, the package assembly configured to route incoming information from the first set of pins to the third IC before reaching the first IC or the second IC; and
the second set of pins is coupled between the nonvolatile memory of the first IC and the exterior of the package assembly, the package assembly configured to route incoming information from the second set of pins to the first IC before reaching the second IC or the third IC.

11. The apparatus of claim 1, wherein:
the AI engine of the third IC comprises a main AI engine; and
the AI engine of the PIM of the second IC comprises an ancillary AI engine relative to the main AI engine.

12. The apparatus of claim 1, wherein:
the package assembly comprises a first package assembly; and
the apparatus further comprises a second package assembly coupled to the first package assembly, the second package assembly comprising a fourth IC.

13. The apparatus of claim 12, wherein:
the fourth IC comprises a system-on-chip (SoC); and
the SoC comprises an AI engine.

14. The apparatus of claim 13, wherein:
the AI engine of the SoC comprises a main AI engine; and
the AI engine of the third IC comprises an ancillary AI engine relative to the main AI engine.

15. The apparatus of claim 14, wherein:
the SoC is configured to assign one or more tasks to the ancillary AI engine for the ancillary AI engine to perform the one or more tasks.

16. The apparatus of claim 13, wherein:
the second package assembly comprises a fifth IC; and
the fifth IC comprises DRAM.

17. The apparatus of claim 12, further comprising:
a printed circuit board (PCB), wherein:
the first package assembly is mounted to the PCB; and
the second package assembly is mounted to the PCB.

18. The apparatus of claim 17, further comprising:
a housing, wherein:
the housing encloses the PCB, the first package assembly, and the second package assembly; and
the apparatus comprises a mobile device.

19. An apparatus comprising:
a package assembly comprising:
a first integrated circuit (IC) including nonvolatile memory;
a second IC including dynamic random-access memory (DRAM) that includes processor-in-memory (PIM) circuitry, the PIM circuitry comprising an artificial intelligence (AI) engine; and
multiple pins coupled to the first IC and the second IC, the multiple pins exposed to an exterior of the package assembly.

20. A method comprising:
providing a first integrated circuit (IC) including nonvolatile memory;
providing a second IC including dynamic random-access memory (DRAM) that includes processor-in-memory (PIM), the PIM comprising an artificial intelligence (AI) engine;
providing a third IC including an AI engine; and
encasing the first IC, the second IC, and the third IC in a package.
